(19) United States
(12) Patent Application Publication
(10) Pub. No.: US 2013/0171789 A1
(43) Pub. Date: Jul. 4, 2013

(54) METHOD FOR MANUFACTURING SEMICONDUCTOR DEVICE

(71) Applicants: Ling-Chun Chou, Yun-Lin County (TW); Shin-Chuan Huang, Tainan City (TW); I-Chang Wang, Tainan City (TW); Ching-Wen Hung, Tainan City (TW); Buo-Chin Hsu, New Taipei City (TW); Yi-Han Ye, Tainan City (TW)

(72) Inventors: Ling-Chun Chou, Yun-Lin County (TW); Shin-Chuan Huang, Tainan City (TW); I-Chang Wang, Tainan City (TW); Ching-Wen Hung, Tainan City (TW); Buo-Chin Hsu, New Taipei City (TW); Yi-Han Ye, Tainan City (TW)

(21) Appl. No.: 13/342,993

(22) Filed: Jan. 4, 2012

(51) Int. Cl. H01L 21/336

(52) U.S. Cl. 438/283; 257/E21.421

(57) ABSTRACT

A method for manufacturing a semiconductor device includes providing a substrate having a first gate structure and a second gate structure formed thereon; blanketly forming a seal layer covering the first gate structure and the second gate structure on the substrate; performing a first ion implantation to form first light-doped drains (LDDs) in the substrate respectively at two sides of the first gate structure; and performing a second ion implantation to form second LDDs in the substrate respectively at two sides of the second gate structure; wherein at least one of the first ion implantation and the second ion implantation is performed to penetrate through the seal layer.

### BACKGROUND OF THE INVENTION

1. Field of the Invention

The present invention generally relates to a method for manufacturing a semiconductor device, and more particularly, to a method for manufacturing a semiconductor device capable of improving ultra shallow junction (USJ).

2. Description of the Prior Art

Size reduction of the metal-oxide-semiconductor field-effect transistor (MOSFET) has enabled the continued improvement in performance, density, and cost per unit function of integrated circuits over the past few decades. As the gate length of the conventional MOSFET is reduced, the interaction of the source and drain with the channel is increased resulting in gained influence on the channel potential. Consequently, a transistor with a short gate length suffers from problems related to the inability of the gate to substantially control the on/off states of the channel. Phenomena such as reduced gate control associated with transistors having short channel lengths are known as short-channel effects (SCE). To suppress SCE problem, approaches such as increasing body doping concentration, reducing gate oxide thickness, and forming ultra-shallow source/drain junctions are developed.

The conventional method for forming ultra-shallow junctions is to implant dopants into the shallow surface of the substrate by a low energy ion implantation. Since the doping concentration is increased while the device size is deceased, it is getting more and more important to precisely control dopant diffusion. However, it is also getting more and more difficult to form ultra shallow junction as the device size keeps shrinking. Therefore a method for manufacturing a semiconductor device that is capable of improving ultra shallow junction thus to provide a semiconductor device having improved performance is still in need.

### SUMMARY OF THE INVENTION

According to an aspect of the present invention, a method for manufacturing a semiconductor device is provided. The method includes providing a substrate having a first gate structure and a second gate structure formed thereon; blanketly forming a seal layer covering the first gate structure and the second gate structure on the substrate; performing a first ion implantation to form first lightly-doped drains (LDDs) in the substrate respectively at two sides of the first gate structure; performing a second ion implantation to form second LDDs in the substrate respectively at two sides of the second gate structure; wherein at least one of the first ion implantation and the second ion implantation penetrates the seal layer.

According to the method for manufacturing a semiconductor device provided by the present invention, the seal layer is blanketly formed on the substrate before performing the first ion implantation or/and the second ion implantation. Therefore at least one of the first ion implantation and the second ion implantation is performed to penetrate the seal layer to form the first LDDs or/and the second LDDs. Because of the seal layer, the first LDDs or/and the second LDDs obtain the expected ultra shallow junction profile. Accordingly, SCE is efficiently suppressed and performance of the semiconductor device is improved by improving the ultra shallow junction profile of the LDDs even when the device size keeps shrinking.

These and other objectives of the present invention will no doubt become obvious to those of ordinary skill in the art after reading the following detailed description of the preferred embodiment that is illustrated in the various Figures and drawings.

### BRIEF DESCRIPTION OF THE DRAWINGS

FIGS. 1-3 and 9-13 are schematic drawings illustrating a method for manufacturing a semiconductor device provided by a first preferred embodiment of the present invention, wherein

FIG. 2 is a schematic drawing in a step subsequent to FIG. 1, and

FIG. 3 is a schematic drawing in a step subsequent to FIG. 2.

FIGS. 4-6 and 9-13 are schematic drawings illustrating a method for manufacturing a semiconductor device provided by a second preferred embodiment of the present invention, wherein

FIG. 5 is a schematic drawing in a step subsequent to FIG. 4, and

FIG. 6 is a schematic drawing in a step subsequent to FIG. 5.

FIGS. 7-8 are schematic drawings illustrating a method for manufacturing a semiconductor device provided by a third preferred embodiment of the present invention, wherein FIG. 8 is a schematic drawing in a step subsequent to FIG. 7.

FIGS. 9-13 are schematic drawings in steps subsequent to FIGS. 3, 6. and 8, wherein

FIG. 9 and FIG. 10 are schematic drawings in a step subsequent to FIGS. 3, 6, and 8,

FIG. 11 is a schematic drawing in a step subsequent to FIG. 9 and FIG. 10,

FIG. 12 is a schematic drawing in a step subsequent to FIG. 11, and

FIG. 13 is a schematic drawing in a step subsequent to FIG. 12.

FIGS. 14-18 are schematic drawings illustrating a method for manufacturing a semiconductor device provided by a fourth preferred embodiment of the present invention, wherein

FIG. 15 and FIG. 16 are schematic drawings in a step subsequent to FIG. 14,

FIG. 17 is a schematic drawing in a step subsequent to FIG. 15 and FIG. 16, and

FIG. 18 is a schematic drawing in a step subsequent to FIG. 17.

### DETAILED DESCRIPTION

Please refer to FIGS. 1-3, which are schematic drawings illustrating a method for manufacturing a semiconductor device provided by a first preferred embodiment of the present invention. As shown in FIG. 1, the preferred embodiment provides a substrate 100 having a first region 102 and a second region 104 defined thereon. A first gate structure 110 is formed in the first region 102 and a second gate structure 112 is formed in the second region 104, respectively. A plurality of shallow trench isolations (STIs) 106 is formed in the substrate 100 to provide electrical isolation. According to the preferred embodiment, the first gate structure 110 is a gate structure of a p-MOS and the second gate structure 112 is a gate structure of an n-MOS. As shown in FIG. 1, the first gate structure 110 and the second gate structure 112 respectively and sequentially includes a gate dielectric layer 110a and 112a, a gate conductive layer 110b and 112b, and a patterned hard mask 110c and 112c for defining the gate structures 110/112.

Please still refer to FIG. 1. Next, a seal layer 120 is blanketly formed on the substrate 100. As shown in FIG. 1, the seal layer 120 covers the first gate structure 110 and the second gate structure 112. According to the preferred embodiment, the seal layer 120 includes silicon oxide, silicon nitride, silicon nitride containing carbon, silicon carbon nitride (SiCN), hexachlorodisilane (HCD), or carbon doped hexachlorodisilane (CHCD), but not limited to this. The seal layer 120 includes a thickness, and the thickness is between 25 angstroms (Å) and 50 Å. After forming the seal layer 120, an insulating layer (not shown) having an etching rate different from an etching rate of the seal layer 120 is formed on the substrate 100 and followed by performing an etching back process. Consequently, a portion of the insulating layer is removed and a first spacer 122 is formed respectively on sidewalls of the first gate structure 110 and sidewalls of the second gate structure 112. As shown in FIG. 1, a portion of the seal layer 120 covered by the first spacer 122 serves as a part of the first spacer 122.

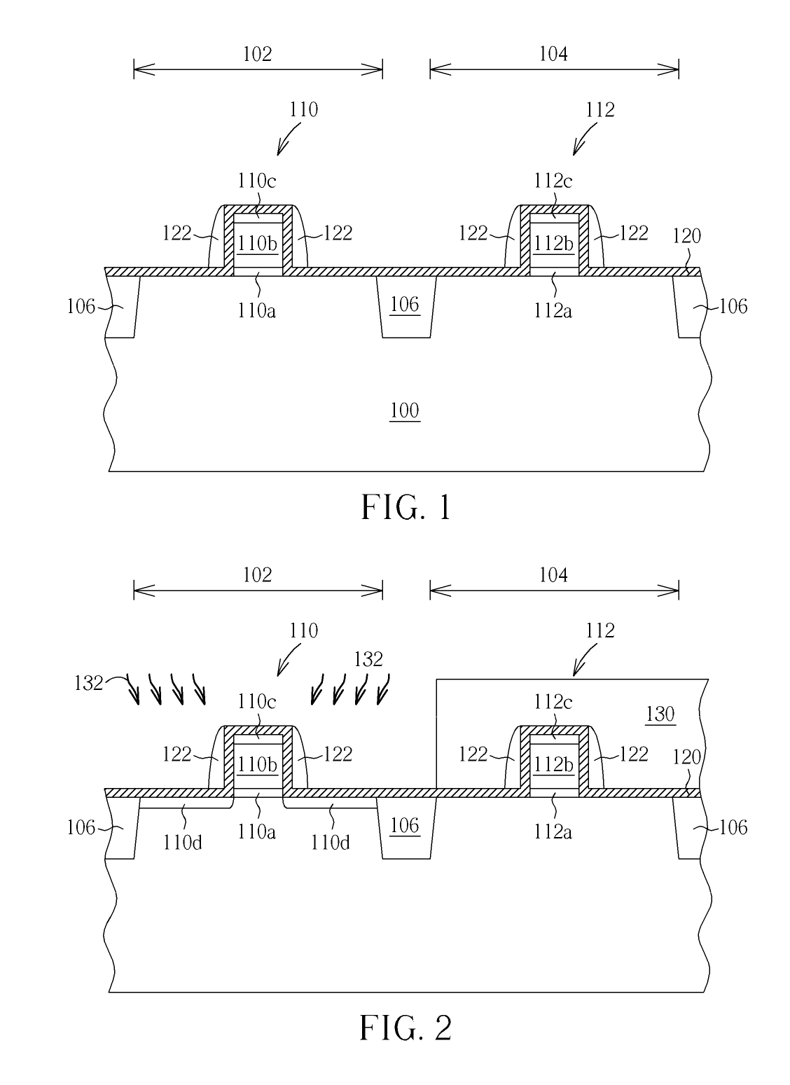

Please refer to FIG. 2. After forming the first spacer 122, a patterned mask 130, for example but not limited to a patterned photoresist, is formed on the substrate 100. The patterned mask 130 covers the second region 104 but exposes the first region 102. Subsequently, a first ion implantation 132, for example but not limited to a tilted ion implantation, is performed as shown in FIG. 2. The first ion implantation 132 is performed to implant p-type dopants such as boron (B) or boron difluoride (BF₂) into the substrate 100 at two sides of the first gate structure 110, and thus first LDDs 110d are formed in the substrate 100 respectively at the two sides of the first gate structure 110. It is noteworthy that the first ion implantation 132 penetrates the seal layer 120 as shown in FIG. 2. Furthermore, the first ion implantation 132 can use dopants of different conductivity type, different energy, and different implant angle to form other doped regions with the patterned mask 130 still serving as the implant mask. For example, n-type dopants such as phosphorous (P) or arsenic (Ar) are implanted to form pocket regions (not shown), and germanium (Ge), fluorine (F), or carbon (C) can be co-implanted.

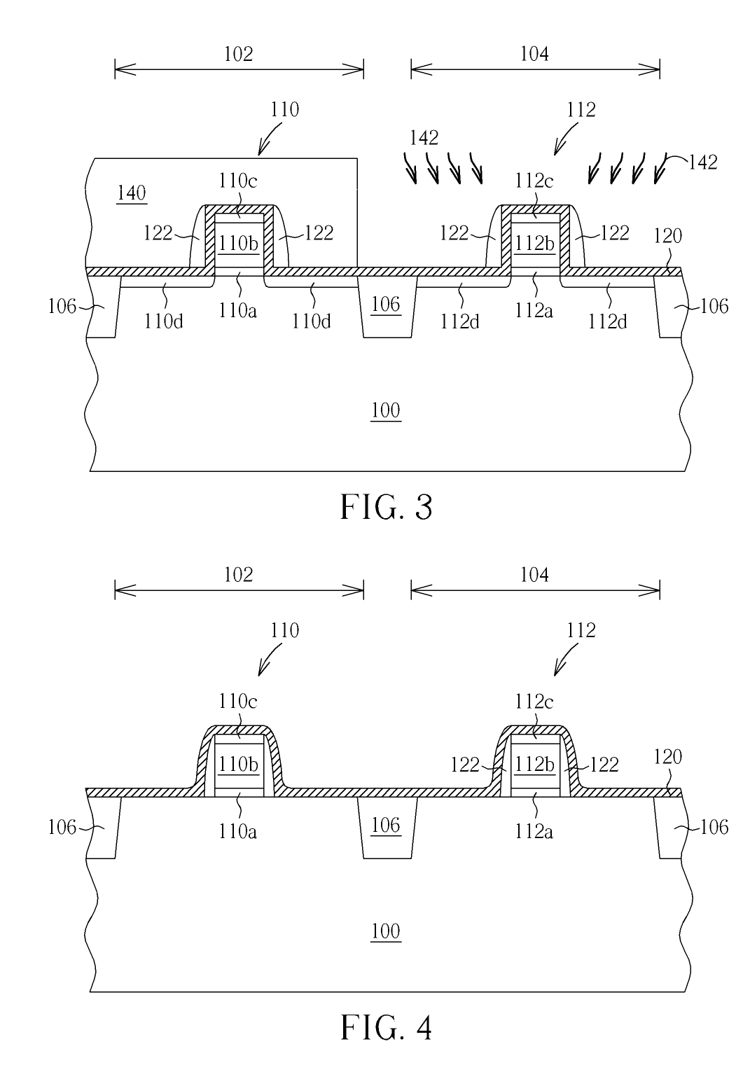

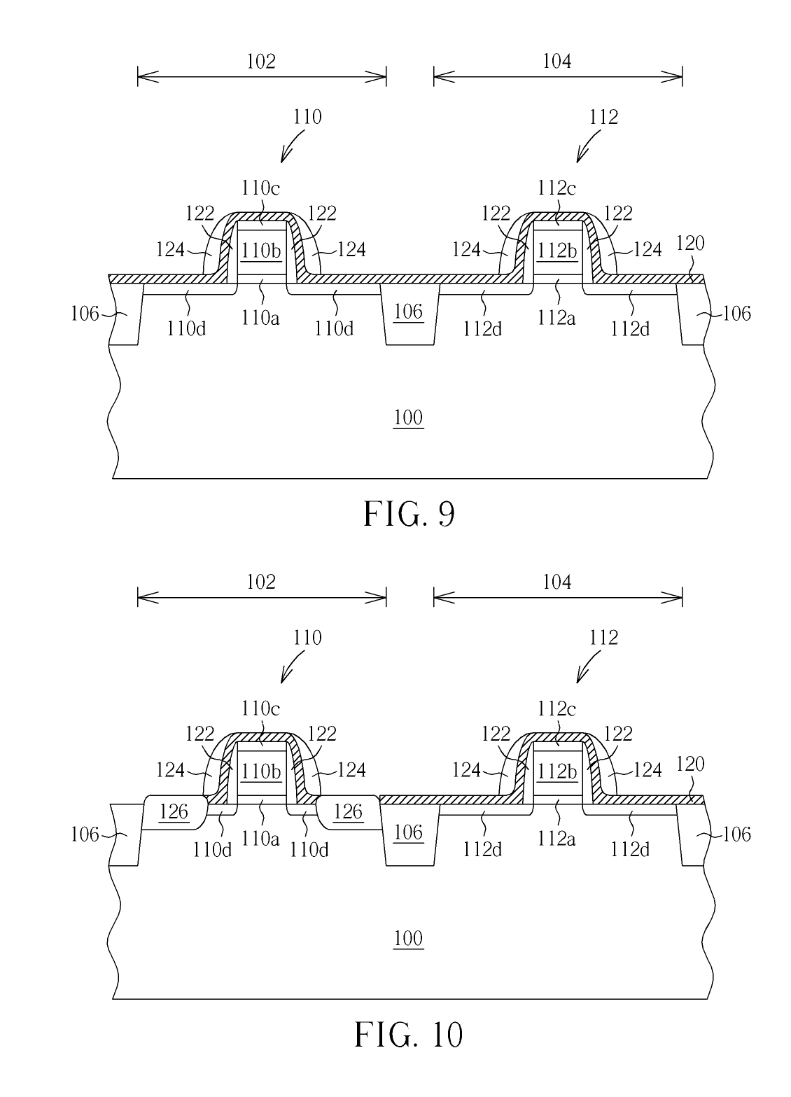

Please refer to FIG. 3. After forming the first LDDs 110d, the patterned mask 130 is removed and followed by forming another patterned mask 140 on the substrate 100. The patterned mask 140 covers the first region 102 but exposes the second region 104. Subsequently, a second ion implantation 142, for example but not limited to a tilted ion implantation, is performed as shown in FIG. 3. The second ion implantation 142 is performed to implant n-type dopants such as P or As into the substrate 100 at two sides of the second gate structure 112, and thus second LDDs 112d are formed in the substrate 100 respectively at the two sides of the second gate structure 112. Also, the second ion implantation 142 can use dopants of different conductivity type, different energy, and different implant angle to form other doped regions with the patterned mask 140 still serving as the implant mask. For example, p-type dopants such as B or BF₂ are implanted to form pocket regions (not shown), and Ge, F, or C can be co-implanted. It is noteworthy that the second ion implantation 142 also penetrates the seal layer 120 as shown in FIG. 3. Then, the patterned mask 140 is removed to expose the seal layer 120 for performing following steps (shown in FIGS. 9-12). It is noteworthy that in the preferred embodiment, p-type LDDs are formed before the n-type LDD, however those skilled in the art would easily realize that the n-type LDDs can be formed before the p-type LDDs according to a modification of the preferred embodiment.

According to the method for manufacturing a semiconductor device provided by the first preferred embodiment, the seal layer 120 is blanketly formed on the substrate 100 before forming the p-type LDDs and the n-type LDDs. Therefore both of the first ion implantation 132 and the second ion implantation 142 are performed to penetrate the seal layer 120. In other words, the n-type dopants and the p-type dopants must penetrate the seal layer 120 and thus to get into the substrate 100. Accordingly, both of the first LDDs 110d and the second LDDs 112d obtain the expected and improved ultra shallow junction.

Please refer to FIGS. 4-6, which are schematic drawings illustrating a method for manufacturing a semiconductor device provided by a second preferred embodiment of the present invention. It is noteworthy that elements the same in both first and second preferred embodiments are designated by the same numerals. The differences between the first preferred embodiment and the second preferred embodiment are: the second preferred embodiment is to form a first spacer 122 respectively on sidewalls of the first gate structure 110 and sidewalls of the second gate structure 112 immediately after providing the substrate 100 having the first gate structure 110 and the second gate structure 112. A width of the first spacer 122 is not larger than 65 Å, but not limited to this. After forming the first spacer 122, a seal layer 120 is blanketly formed on the substrate 100. Since the material choice and the thickness of the seal layer 120 are the same in both of the first and second preferred embodiments, those details are omitted herein in the interest of brevity.

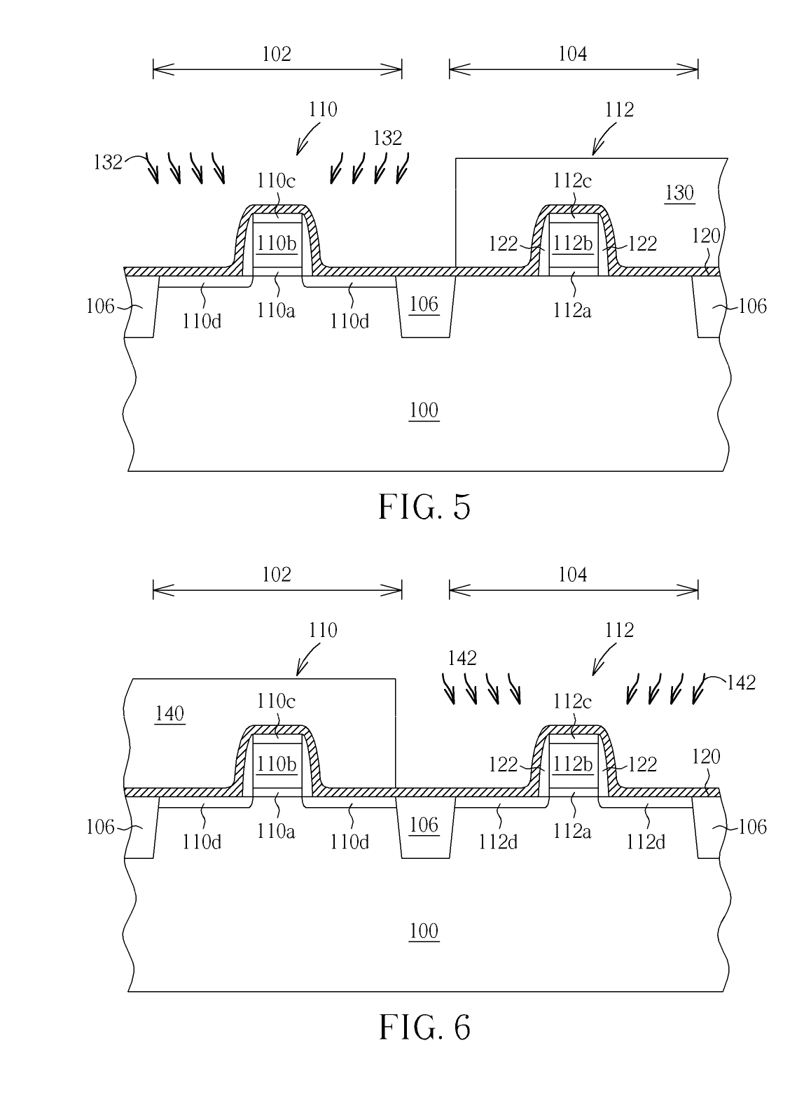

Please refer to FIG. 5. After forming the seal layer 120, a patterned mask 130, for example but not limited to a patterned photoresist, is formed on the substrate 100. The patterned mask 130 covers the second region 104 but exposes the first region 102. Subsequently, a first ion implantation 132, for example but not limited to a tilted ion implantation, is performed as shown in FIG. 5. The first ion implantation 132 is performed to implant the above-mentioned dopants into the substrate 100 at two sides of the first gate structure 110, and thus first LDDs 110d are formed in the substrate 100 respectively at the two sides of the first gate structure 110. It is noteworthy that the first ion implantation 132 penetrates the seal layer 120 as shown in FIG. 5.

After forming the first LDDs 110d, the patterned mask 130 is removed and followed by forming another patterned mask 140 on the substrate 100. The patterned mask 140 covers the first region 102 but exposes the second region 104. Subsequently, a second ion implantation 142, for example but not limited to a tilted ion implantation, is performed as shown in FIG. 6. The second ion implantation 142 is performed to implant the abovementioned dopants into the substrate 100 at two sides of the second gate structure 112, and thus second LDDs 112d are formed in the substrate 100 respectively at the two sides of the second gate structure 112. It is noteworthy that the second ion implantation 142 also penetrates the seal layer 120 as shown in FIG. 6. Then, the patterned mask 140 is removed to expose the seal layer 120 for performing following steps (shown in FIGS. 9-12). It is noteworthy that in the preferred embodiment, p-type LDDs are formed before the n-type LDD, however those skilled in the art would easily realize that the n-type LDDs can be formed before the p-type LDDs according to a modification of the preferred embodiment.

According to the method for manufacturing a semiconductor device provided by the second preferred embodiment, the seal layer 120 is blanketly formed on the substrate 100 after forming the first spacer 122, therefore the width of the first spacer 122 can be controlled more precisely. Furthermore, the seal layer 120 is protected from the etching back process performed for forming the first spacer 122. More important, the seal layer 120 is formed before forming the p-type LDDs and the n-type LDDs, therefore both of the first ion implantation 132 and the second ion implantation 142 are performed to penetrate the seal layer 120. In other words, the n-type dopants and the p-type dopants must penetrate the seal layer 120 and thus to get into the substrate 100. Accordingly, both of the first LDDs 110d and the second LDDs 112d obtain the expected and improved ultra shallow junction.

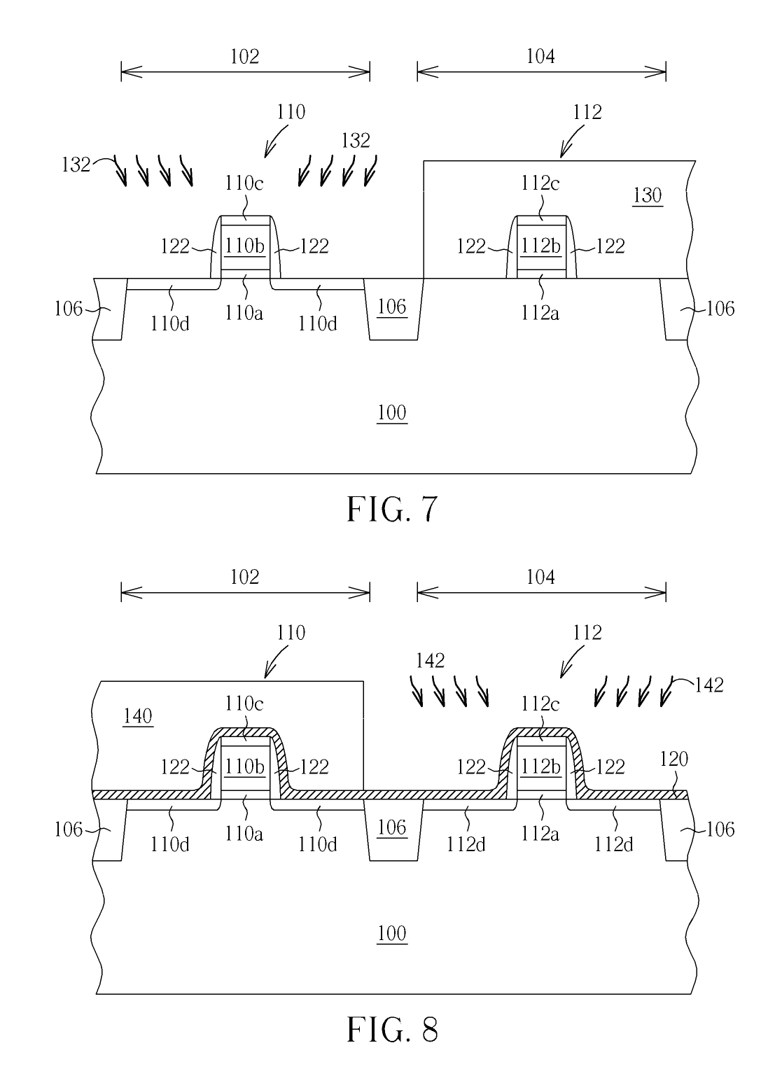

Please refer to FIGS. 7-12, which are schematic drawings illustrating a method for manufacturing a semiconductor device provided by a third preferred embodiment of the present invention. It is noteworthy that elements the same in the first, second, and third preferred embodiments are designated by the same numerals. The differences between the third preferred embodiment and the first/second preferred embodiments are: the third preferred embodiment is to form a first spacer 122 respectively on sidewalls of the first gate structure 110 and sidewalls of the second gate structure 112 immediately after providing the substrate 100 having the first gate structure 110 and the second gate structure 112. As mentioned above, a width of the first spacer 122 is not larger than 65 Å, but not limited to this. After forming the first spacer 122, a patterned mask 130, for example but not limited to a patterned photoresist, is formed on the substrate 100. The patterned mask 130 covers the second region 104 but exposes the first region 102. Subsequently, a first ion implantation 132, for example but not limited to a tilted ion implantation, is performed as shown in FIG. 7. The first ion implantation 132 is performed to implant p-type dopants, preferably includes boron hydride cluster in the preferred embodiment, into the substrate 100 at two sides of the first gate structure 110, and thus first LDDs 110d are formed in the substrate 100 respectively at the two sides of the first gate structure 110.

Please refer to FIG. 8. After forming the first LDDs 110d by performing the first ion implantation 132, a seal layer 120 is blanketly formed on the substrate 100. Since the material choice and the thickness of the seal layer 120 are the same in both of the first, second, and third preferred embodiments, those details are omitted herein in the interest of brevity. After forming the seal layer 120, a patterned mask 140, for example but not limited to a patterned photoresist, is formed on the substrate 100. The patterned mask 140 covers the first region 102 but exposes the second region 104. Subsequently, a second ion implantation 142, for example but not limited to a tilted ion implantation, is performed as shown in FIG. 8. The second ion implantation 142 is performed to implant n-type dopants into the substrate 100 at two sides of the second gate structure 112, and thus second LDDs 112d are formed in the substrate 100 respectively at the two sides of the second gate structure 112. It is noteworthy that the second ion implantation 142 penetrates the seal layer 120 as shown in FIG. 8.

According to the method for manufacturing a semiconductor device provided by the third preferred embodiment, when the first implantation 132 includes the larger dopants such as boron hydride cluster, the ultra shallow junction of the first LDDs 132 is spontaneously improved. Therefore the seal layer 120 can be formed after performing the first ion implantation 132. Furthermore, since the second ion implantation 142 is performed after forming the seal layer 120, the second ion implantation 142 is performed to penetrate the seal layer 120. In other words, the n-type dopants must penetrate the seal layer 120 and thus to get into the substrate 100. Consequently, both of the first LDDs 110d and the second LDDs 112d obtain the expected and improved ultra shallow junction.

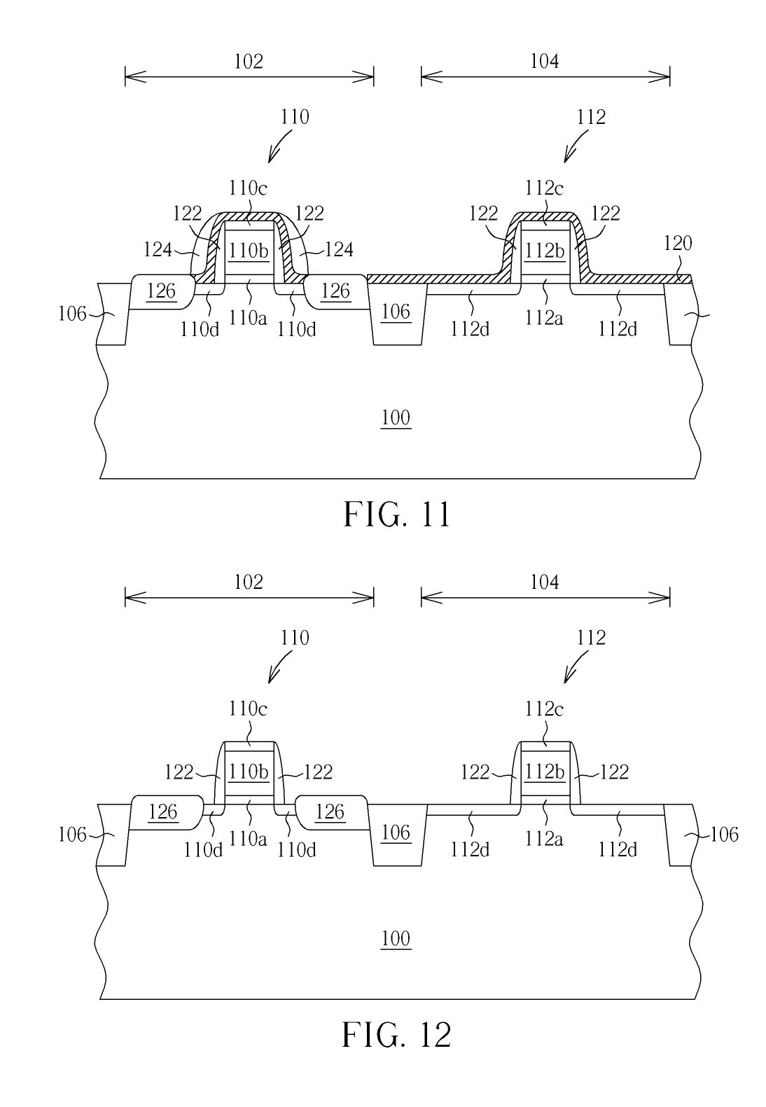

Please refer to FIGS. 9-13. It is noteworthy that steps depicted in FIGS. 9-13 is performed after forming the first LDDs 110d and the second LDDs 112d and after removing the patterned mask 140. In other words, FIGS. 9-13 depict steps following performed in the first, second, and third preferred embodiments. After removing the patterned mask 140 as mentioned in the first, second, and third preferred embodiments, disposal spacers 124 are sequentially formed on sidewalls of the first gate structure 110 and sidewalls of the second gate structure 112 as shown in FIG. 10. Or a disposal spacer 124 is formed only on sidewalls of the first gate structure 110 as shown in FIG. 11.

Please refer to FIGS. 10 and 11. After forming the disposal spacer 124, a recess (not shown) is formed in the substrate 100 respectively at two sides of the disposal spacer 124 on the sidewalls of the first gate structure 110. Subsequently, a selective epitaxial growth (SEG) process is performed to form an epitaxial layer 126, such as a silicon-germanium (SiGe) epitaxial layer, along the surface of the substrate 100 in the recesses. In other words, the preferred embodiment is integrated with the strain silicon technology. Because the lattice constant of the epitaxial SiGe layer is larger than that of the silicon, such characteristic is employed to cause alteration to the band structure of the silicon in the channel region of the substrate 100. Accordingly, the carrier mobility and the speed performance of the p-MOS are improved.

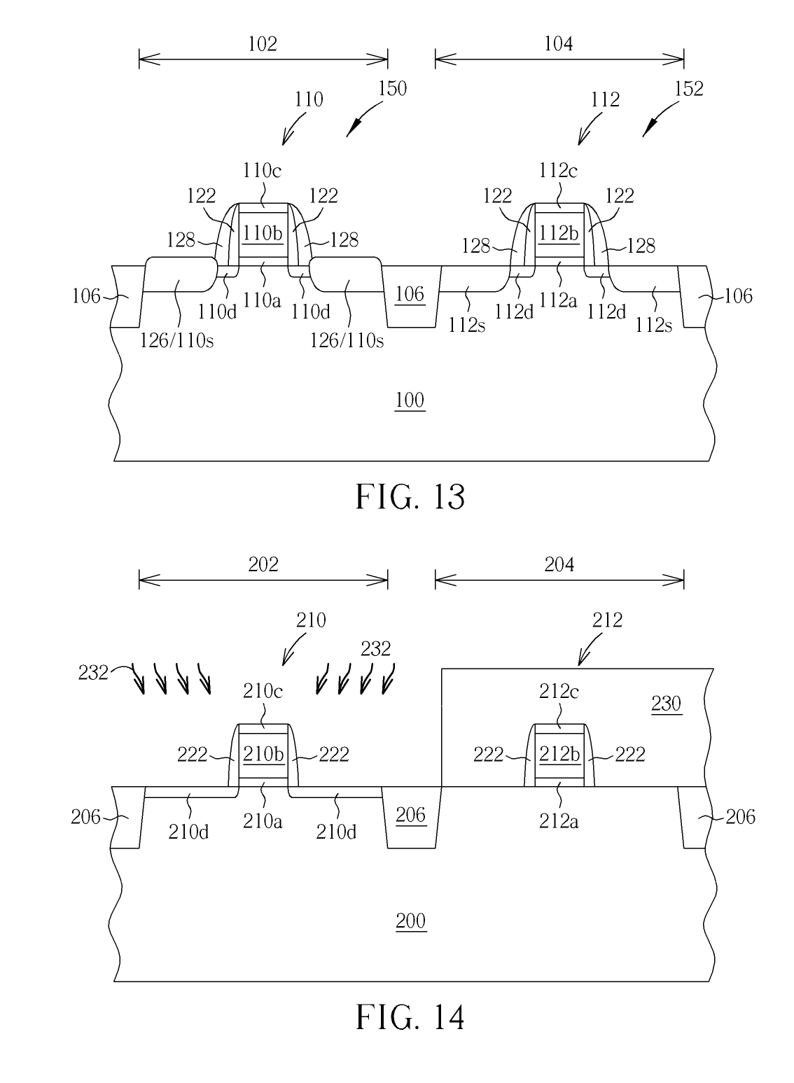

Please still refer to FIGS. 10 and 11. After forming the epitaxial layer 126, the disposal spacer 124 and the exposed the seal layer 120 are simultaneously removed and thus to expose the first spacer as shown in FIG. 12. Then, a second spacer 128 is formed to cover the first spacers 122 of the first gate structure 110 and the second gate structure 112 as shown in FIG. 13. Subsequently, a first source/drain 110s including p-type dopants is formed at two sides of the second spacer 128 in the first region 102, and a second source/drain 112s including n-type dopants is formed at two sides of the second spacer 128 in the second region 104. Since the steps for forming the second spacer 128, the first source/drain 110s, and the second source/drain 112s are well-known to those skilled in the art, the details are all omitted in the interest of brevity. It is noteworthy that the first source/drain 110s is formed in the epitaxial layer 126 as shown in FIG. 13 Accordingly, a first MOS transistor device 150 having p-type and a second MOS transistor device 152 having n-type are obtained.

According to the methods for manufacturing a semiconductor device provided by the first, second, and third preferred embodiments, the seal layer 120 can be formed before or after forming the first spacer 122. Furthermore, when the seal layer 120 is formed after forming the first spacer 122, the seal layer 120 can be formed before or after performing the ion implantation for forming the p-type LDD, depending on the dopants used in the ion implantation. Since the seal layer 120 and the disposal spacer 124 are simultaneously removed, the methods for manufacturing a semiconductor device provided by the first, second, and third preferred embodiments render no influences to the following steps such as the steps for forming the first source/drain 110s and the second source/drain 112s. In other words, the methods for manufacturing a semiconductor device provided by the first, second, and third preferred embodiments are capable of improving the ultra shallow junctions of the first LDDs 110d and the second LDDs 112d without excessively increasing process complexity. Accordingly, SCE which always adversely affects the first MOS transistor device 150 and the second MOS transistor device 152, is efficiently suppressed.

Please refer to FIGS. 14-18, which are schematic drawings illustrating a method for manufacturing a semiconductor device provided by a fourth preferred embodiment of the present invention. As shown in FIG. 14, the preferred embodiment provides a substrate 200 having a first region 202 and a second region 204 defined thereon. A first gate structure 210 is formed in the first region 202, and a second gate structure 212 is formed in the second region 204, respectively. A plurality of STIs 206 is formed in the substrate 200 to provide electrical isolation. According to the preferred embodiment, the first gate structure 210 is a gate structure of a p-MOS and the second gate structure 212 is a gate structure of an n-MOS. As shown in FIG. 14, the first gate structure 210 and the second gate structure 212 respectively and sequentially includes a gate dielectric layer 210a and 212a, a gate conductive layer 210b and 212b, and a patterned hard mask 210c and 212c for defining the gate structures 210/212.

Please still refer to FIG. 14. Next, a first spacer 222 is respectively formed on sidewalls of the first gate structure 210 and sidewalls of the second gate structure 212. After forming the first spacer 222, a patterned mask 230, for example but not limited to a patterned photoresist, is formed on the substrate 200. The patterned mask 230 covers the second region 204 but exposes the first region 202. Subsequently, a first ion implantation 232, for example but not limited to a tilted ion implantation, is performed as shown in FIG. 14. The first ion implantation 232 is performed to implant p-type dopants, preferably includes boron hydride cluster in the preferred embodiment, into the substrate 200 at two sides of the first gate structure 210, and thus first LDDs 210d are formed in the substrate 200 respectively at the two sides of the first gate structure 210.

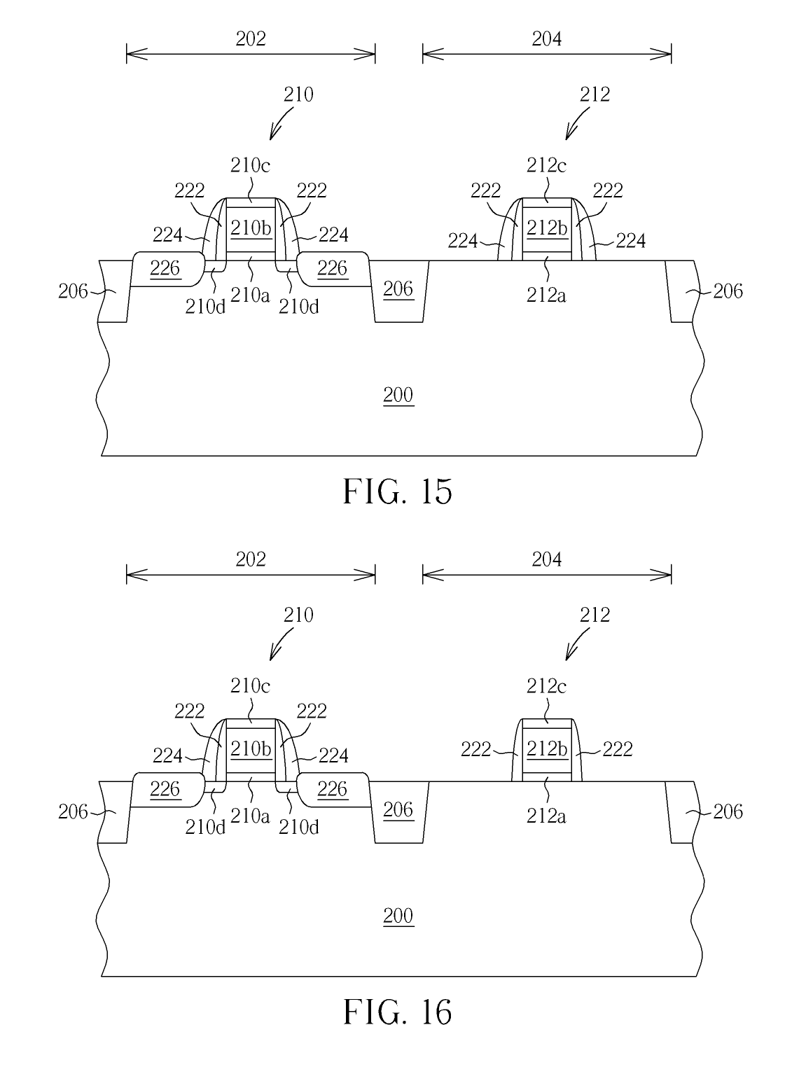

Please refer to FIG. 15 and FIG. 16. After performing the first ion implantation 320 to form the first LDDs 210d, the patterned mask 230 is removed. Subsequently, disposal spacers 224 are sequentially formed on the sidewalls of the first gate structure 210 and on the second gate structure 212 as shown in FIG. 15. Or a disposal spacer 224 is formed only on sidewalls of the first gate structure 210 as shown in FIG. 16. After forming the disposal spacer 224, a recess (not shown) is respectively formed in the substrate 200 at two sides of disposal spacer 224 on the sidewalls of the first gate structure 210 and followed by performing a SEG process. Consequently, an epitaxial layer 226, such as a SiGe epitaxial layer, is respectively formed in the recesses along the surface of the substrate 200.

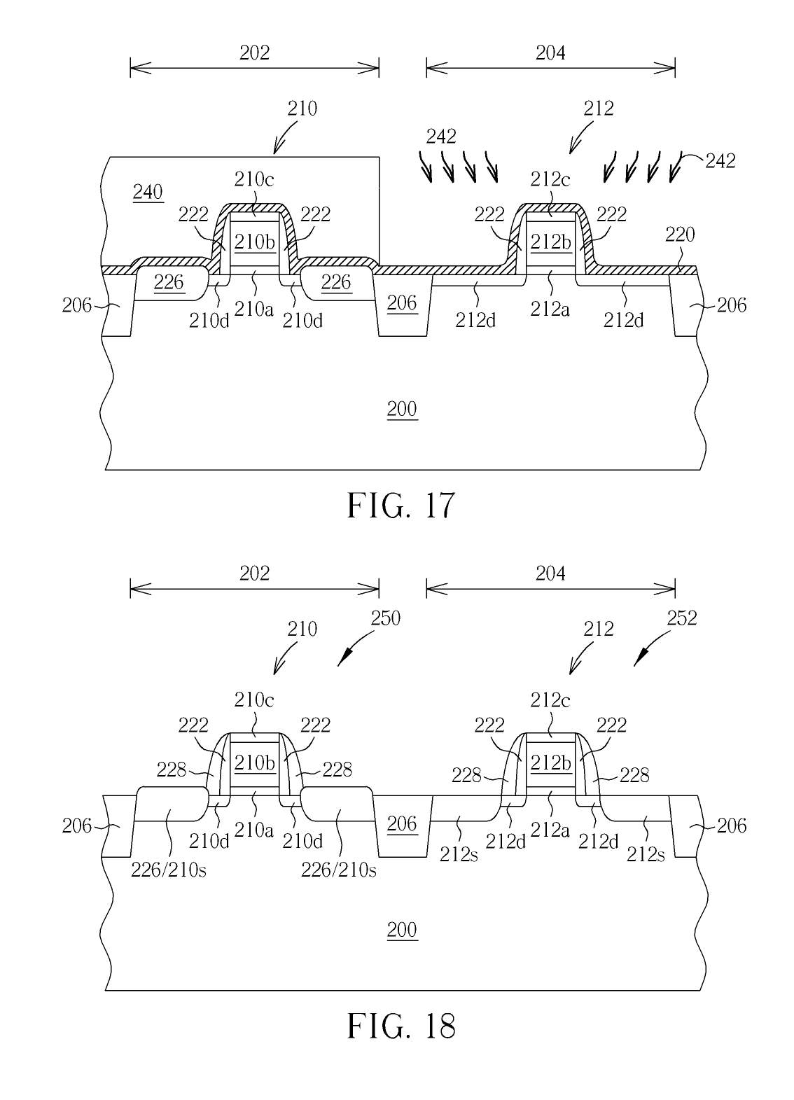

Please refer to FIG. 17. Then, the disposal spacer 224 is removed and a seal layer 220 is blanketly formed on the substrate 200. Subsequently, another patterned mask 240 is formed on the substrate 200. The patterned mask 240 covers the first region 202 but exposes the second region 204. Subsequently, a second ion implantation 242, for example but not limited to a tilted ion implantation, is performed as shown in FIG. 17. The second ion implantation 242 is performed to implant n-type dopants into the substrate 200 at two sides of the second gate structure 212, and thus second LDDs 212d are formed in the substrate 200 respectively at the two sides of the second gate structure 212. It is noteworthy that the second ion implantation 242 penetrates the seal layer 220 as shown in FIG. 17.

Please refer to FIG. 18. After performing the second ion implantation 242 to form the second LDDs 212d, the patterned mask 240 and the seal layer 220 are all removed. Then, a second spacer 228 is formed on sidewalls of the first gate structure 210 and sidewalls of the second gate structure 212 as shown in FIG. 18. Subsequently, a first source/drain 210s including p-type dopants is formed at two sides of the second spacer 228 in the first region 202, and a second source/drain 212s including n-type dopants is formed at two sides of the second spacer 228 in the second region 204. Since the steps for forming the second spacer 228, the first source/drain 210s, and the second source/drain 212s are well-known to those skilled in the art, the details are all omitted in the interest of brevity. It is noteworthy that the first source/drain 210s is formed in the epitaxial layer 226 as shown in FIG. 18. Accordingly, a first MOS transistor device 250 having p-type and a second MOS transistor device 252 having n-type are obtained.

According to the methods for manufacturing a semiconductor device provided by the fourth preferred embodiment, the seal layer 220 is formed after forming the epitaxial layer 226 and removing the disposal spacer 224, and followed by performing the second ion implantation 242. Therefore the second ion implantation 242 is performed to penetrate the seal layer 220. In other words, the n-type dopants must penetrate the seal layer 220 and thus to get into the substrate 200. Accordingly, the second LDDs 212d obtain the expected and improved ultra shallow junction. Furthermore, since the seal later 220 is formed after the SEG process and its related processes (such as removing the disposal spacer 224), the seal layer 220 renders no impact to the SEG process and its related processes. Additionally, because the first implantation 232 includes the larger dopants such as boron hydride cluster, the ultra shallow junction of the first LDDs 232 is spontaneously improved. In other words, the methods for manufacturing a semiconductor device provided by the fourth preferred embodiment is capable of improving the ultra shallow junctions of the first LDDs 210d and the second LDDs 212d without excessively increasing process complexity. Accordingly, SCE, which always adversely affects the first MOS transistor device 250 and the second MOS transistor device 252, is efficiently suppressed.

According to the method for manufacturing a semiconductor device provided by the present invention, the seal layer is blanketly formed on the substrate before performing the first ion implantation or/and the second ion implantation. Therefore at least one of the first ion implantation and the second ion implantation is performed to penetrate the seal layer to form the first LDDs or/and the second LDDs. Because of the seal layer, the first LDDs or/and the second LDDs obtain the expected ultra shallow junction profile. Accordingly, SCE is efficiently suppressed and performance of the semiconductor device is improved by improving the ultra shallow junction profile of the LDDs even when the device size keeps shrinking.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for manufacturing a semiconductor device comprising:
providing a substrate having a first gate structure and a second gate structure formed thereon;
blanketly forming a seal layer covering the first gate structure and the second gate structure on the substrate;
performing a first ion implantation to form first lightly-doped drains (LDDs) in the substrate respectively at two sides of the first gate structure;
performing a second ion implantation to form second LDDs in the substrate respectively at two sides of the second gate structure; wherein at least one of the first ion implantation and the second ion implantation penetrates the seal layer.

2. The method for manufacturing the semiconductor device according to claim 1, wherein the seal layer comprises a thickness, and the thickness is between 25 angstroms (Å) and 50 Å.

3. The method for manufacturing the semiconductor device according to claim 1, wherein the seal layer comprises silicon oxide or silicon nitride.

4. The method for manufacturing the semiconductor device according to claim 1, further comprising forming a first spacer respectively on sidewalls of the first gate structure and sidewalls of the second gate structure.

5. The method for manufacturing the semiconductor device according to claim 4, wherein the seal layer is formed after forming the first spacer.

6. The method for manufacturing the semiconductor device according to claim 5, wherein the first ion implantation and the second ion implantation are performed after forming the seal layer.

7. The method for manufacturing the semiconductor device according to claim 6, wherein the first ion implantation and the second ion implantation both penetrate the seal layer.

8. The method for manufacturing the semiconductor device according to claim 5, wherein the seal layer is formed after performing first ion implantation and before performing the second ion implantation.

9. The method for manufacturing the semiconductor device according to claim 4, wherein the seal layer is formed before forming the first spacer, and a portion of the seal layer is a part of the first spacer.

10. The method for manufacturing the semiconductor device according to claim 9, wherein the first ion implantation and the second ion implantation are performed after forming the first spacer.

11. The method for manufacturing the semiconductor device according to claim 10, wherein the first ion implantation and the second ion implantation both penetrate the seal layer.

12. The method for manufacturing the semiconductor device according to claim 1, further comprising:
forming a first disposal spacer on the sidewalls of the first gate structure;
forming an epitaxial layer in the substrate respective at two sides of the first gate structure; and
removing the first disposal spacer.

13. The method for manufacturing the semiconductor device according to claim 12, further comprising forming a second disposal spacer on the sidewalls of the second gate structure before or after forming the first disposal spacer.

14. The method for manufacturing the semiconductor device according to claim 13, wherein the seal layer, the first disposal spacer, and the second disposal spacer are simultaneously removed.

15. The method for manufacturing the semiconductor device according to claim 12, wherein the seal layer and the first disposal spacer are simultaneously removed.

16. The method for manufacturing the semiconductor device according to claim 15, further comprising following steps performed after removing the seal layer and the first disposal spacer:
forming a second spacer respectively on the sidewalls of the first gate structure and the sidewalls of the second gate structure; and
forming a first source/drain and a second source/drain in the substrate respectively at two sides of the first gate structure and two sides of the second gate structure.

17. The method for manufacturing the semiconductor device according to claim 12, wherein the seal layer is formed after removing the first disposal spacer.

18. The method for manufacturing the semiconductor device according to claim 17, wherein the first ion implantation is performed before forming the first disposal spacer and the second ion implantation is performed after forming the seal layer.

19. The method for manufacturing the semiconductor device according to claim 18, further comprising removing the seal layer after performing the second ion implantation.

20. The method for manufacturing the semiconductor device according to claim 18, further comprising following steps performed after removing the seal layer and the first disposal spacer:
forming a second spacer respectively on the sidewalls of the first gate structure and the sidewalls of the second gate structure; and
forming a first source/drain and a second source/drain in the substrate respectively at two sides of the first gate structure and two sides of the second gate structure.
